(19) United States
(12) Patent Application Publication
(10) Pub. No.: US 2026/0123402 A1
(43) Pub. Date: Apr. 30, 2026

(54) PACKAGE STRUCTURE AND METHOD FOR FORMING THE SAME

(71) Applicant: Taiwan Semiconductor Manufacturing Company, Ltd., Hsinchu (TW)

(72) Inventors: Bang-Li WU, Hsinchu City (TW); Ching WANG, Taichung City (TW); Chien-Chang WANG, Hsinchu City (TW); Kuo-Chin CHANG, Chiayi City (TW); Kathy Wei YAN, Hsinchu (TW)

(21) Appl. No.: 18/926,672

(22) Filed: Oct. 25, 2024

(51) Int. Cl. H01L 23/367; H01L 21/56; H01L 23/00; H01L 23/04; H01L 23/31; H01L 23/373; H01L 23/48; H01L 25/16; H10B 80/00

(52) U.S. Cl. CPC H10W 40/22; H10W 40/25; H10W 74/012; H10W 74/117; H10W 74/121; H10W 74/15; H10W 76/12; H10W 90/00; H10B 80/00; H10W 20/20; H10W 90/722; H10W 90/724; H10W 90/734

(57) ABSTRACT

A package structure and method for forming the same are provided. The package structure includes a first die formed over a substrate, and a first package layer surrounding the first die. The package structure includes a lid structure formed over the first die and package layer and a first thermal interface material (TIM) formed between the first die and the lid structure. The first thermal interface material includes liquid metal. The package structure includes a second TIM formed between the first package layer and the lid structure, and a top surface of the second TIM is higher than a top surface of the first TIM.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Many integrated circuits are typically manufactured on a single semiconductor wafer, and individual dies on the wafer are singulated by sawing between the integrated circuits along a scribe line. The individual dies are typically packaged separately, in multi-chip modules, for example, or in other types of packaging.

New packaging technologies, such as package on package (PoP), have begun to be developed, in which the top package with a device die is bonded to the bottom package, with another device die. By adopting the new packaging technologies, various packages with different or similar functions may be integrated together.

Although existing package structures and methods of fabricating package structure have generally been adequate for their intended purposes, they have not been entirely satisfactory in all respects.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1J show cross-sectional representations of various stages of forming a package structure, in accordance with some embodiments of the disclosure.

FIG. 2 shows a top view of the semiconductor dies and the stacked dies of FIG. 1B, in accordance with some embodiments of the disclosure.

FIG. 3 shows a top view of the semiconductor dies and the stacked dies of FIG. 1E, in accordance with some embodiments of the disclosure.

FIG. 4 shows a top view of the initial pattern of the first TIM and the second TIM of FIG. 1G, in accordance with some embodiments of the disclosure.

FIG. 5 shows a top view of the final pattern of the first TIM and the second TIM of FIG. 1J, in accordance with some embodiments of the disclosure.

FIG. 6 shows a top view of a package structure, in accordance with some embodiments of the disclosure.

FIG. 7A shows a cross-sectional representation of the package structure along the BB′ line of FIG. 6, in accordance with some embodiments of the disclosure.

FIG. 7B shows a cross-sectional representation of the package structure along the CC′ line of FIG. 6, in accordance with some embodiments of the disclosure.

FIG. 8A-8F shows a cross-sectional representation of the package structure, in accordance with some embodiments of the disclosure.

FIGS. 9A-9G shows a cross-sectional representation of a package structure, in accordance with some embodiments of the disclosure.

FIG. 10 shows a cross-sectional representation of a package structure, in accordance with some embodiments of the disclosure.

FIG. 11 shows a cross-sectional representation of a package structure, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The fins described below may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Embodiments for a package structure and method for forming the same are provided. The package structure includes a first die and a second die formed over a substrate. A first package layer surrounds the first die and the second die. A second package layer is formed on the first package layer, not on the first die to create a height difference. The first TIM is formed on the first die and includes liquid metal. Due to the height difference, the liquid metal of the first TIM does not overflow. A second TIM is formed on the second package layer. A lid structure is formed on the first TIM and the second TIM. The height difference between the top surface of the second package layer and the top surface of the first TIM is formed to prevent the liquid metal of the first TIM from flowing out. Therefore, the overflowing issue of the first TIM is resolved.

In addition, the composite TIM with two different thermal conductivity and two different fluidity. The first TIM is directly formed on the first die with high power consumption, and the second TIM is directly formed on the second die with low power consumption. The composite TIMs (the first TIM and the second TIM with different thermal conductivity and fluidity) are formed at different regions to improve the heat-dissipation efficiency. Therefore, the heat-dissipation efficiency of the package structure is improved.

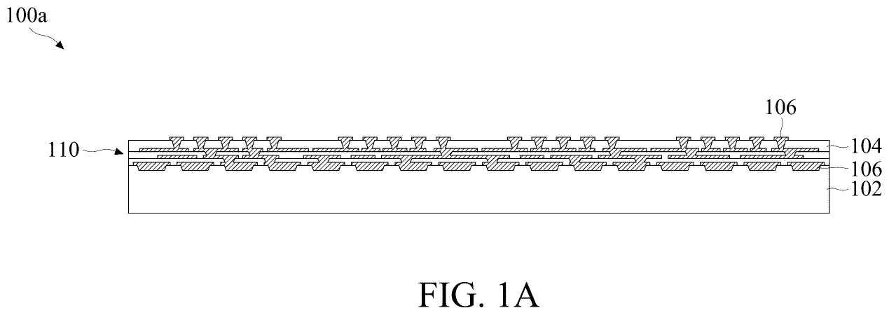

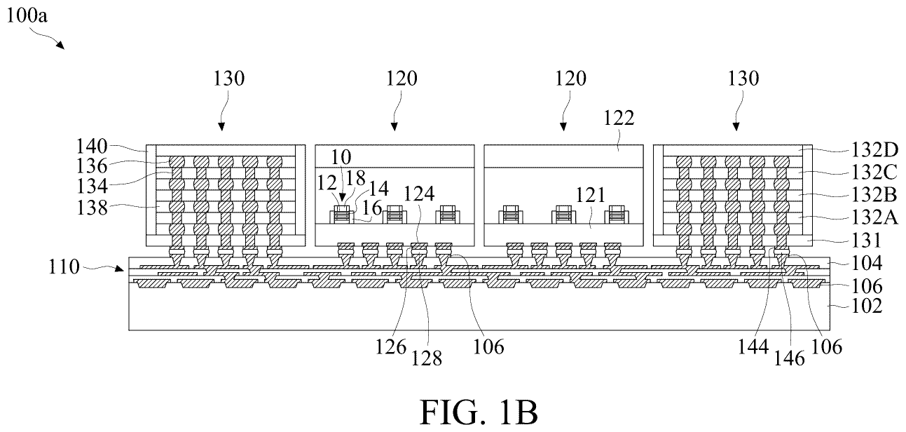

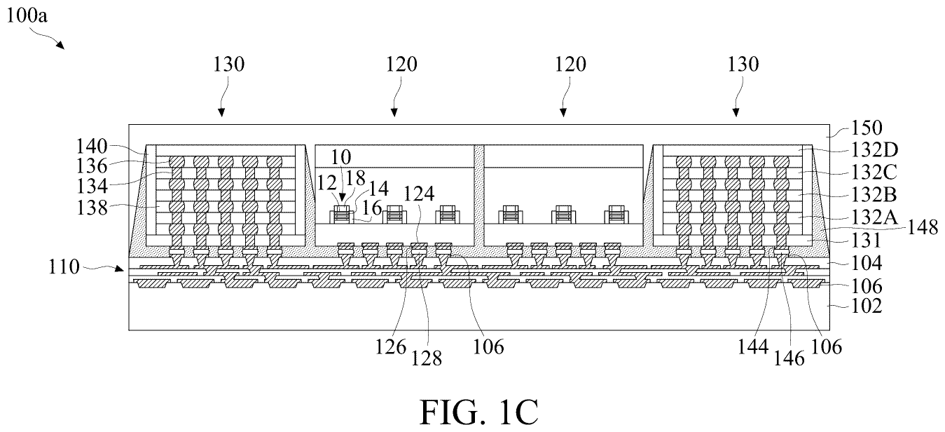

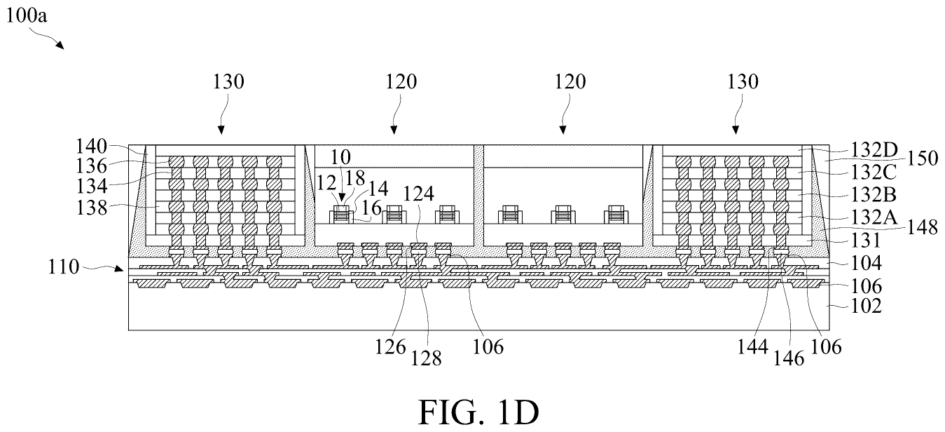

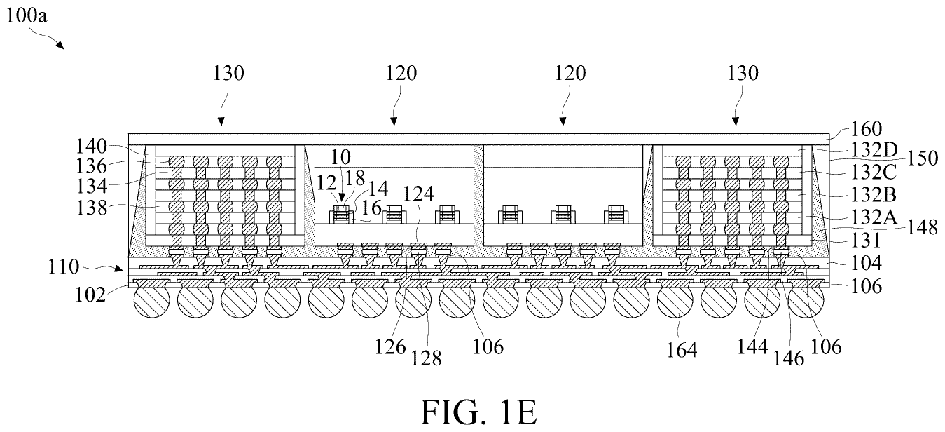

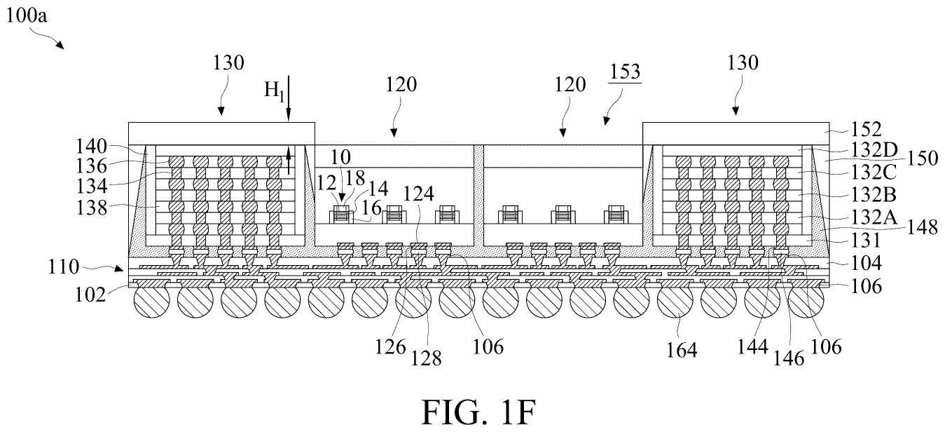

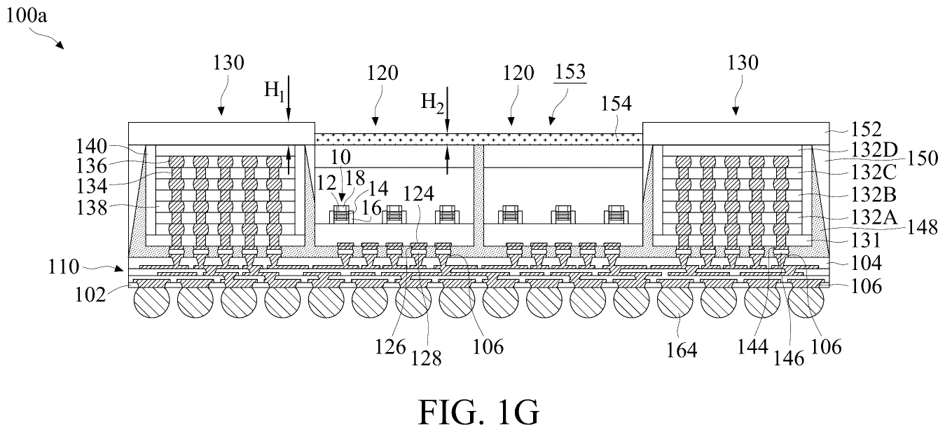

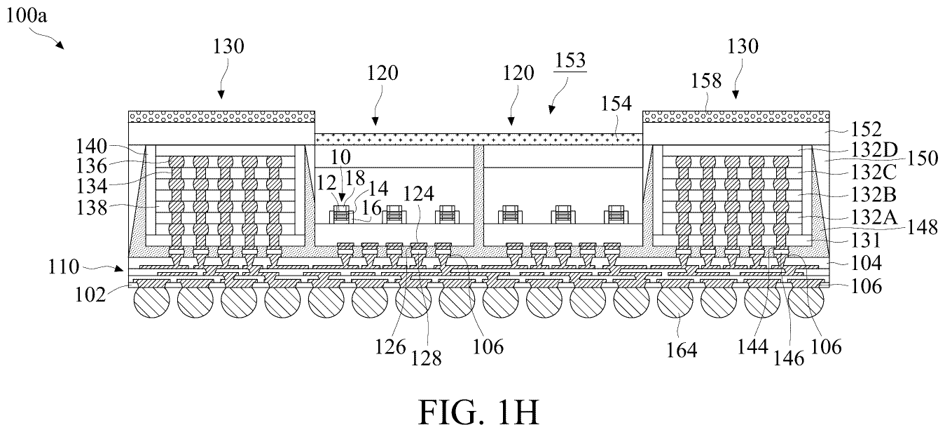

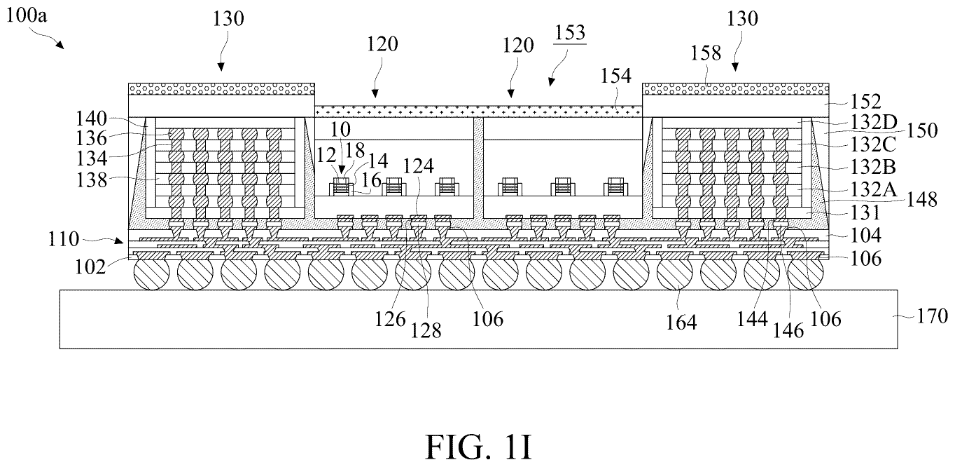

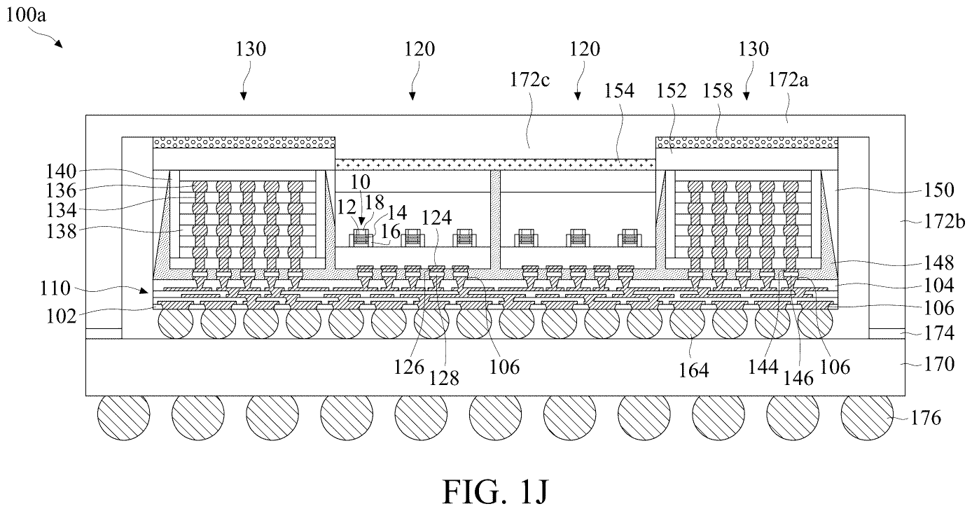

FIGS. 1A-1J show cross-sectional representations of various stages of forming a package structure 100a, in accordance with some embodiments of the disclosure.

Referring to FIG. 1A, a substrate 102 is provided. The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

An interconnect structure 110 is formed over the substrate 102. The interconnect structure 110 may be used as a redistribution (RDL) structure for routing. The interconnect structure 110 includes multiple dielectric layers 104 and multiple conductive layers 106.

The dielectric layers 104 may be made of or include one or more polymer materials. The polymer material(s) may include polybenzoxazole (PBO), polyimide (PI), one or more other suitable polymer materials, or a combination thereof. In some embodiments, the polymer material is photosensitive. In some embodiments, some or all of the dielectric layers 104 are made of or include dielectric materials other than polymer materials. The dielectric material may include silicon oxide, silicon carbide, silicon nitride, silicon oxynitride, one or more other suitable materials, or a combination thereof.

In some embodiments, some of the conductive layers 106 are exposed at or protruding from the top surface of the top of the dielectric layers 104. The exposed or protruding conductive layers 106 may serve as bonding pads where conductive bumps (such as tin-containing solder bumps) and/or conductive pillars (such as copper pillars) will be formed later.

Afterwards, as shown in FIG. 1B, a number of semiconductor dies 120 and a number of stacked dies 130 are formed over the substrate 102, in accordance with some embodiments of the disclosure.

The semiconductor die 120 is sawed from a wafer, and may be a “known-good-die”. The semiconductor die 120 may be a system-on-chip (SoC) chip. In some other embodiments, the semiconductor die 120 is a system on integrated circuit (SoIC) device that includes two or more chips with integrated function. The semiconductor die 120 is disposed over the interconnection structure 110.

The semiconductor die 120 has a substrate 121, a semiconductor structure 10 formed on the substrate 102, and a substrate 122 formed on the semiconductor structure 10. In some embodiments, the semiconductor structure 10 is a logic device. In some embodiments, the semiconductor structure 10 is a gate all around (GAA) transistor structure. In some embodiments, the logic devices are Central Processing Unit (CPU) dies, Graphic Processing Unit (GPU) dies, mobile application dies, Micro Control Unit (MCU) dies, BaseBand (BB) dies, Application processor (AP) dies, or the like.

The semiconductor structure 10 includes nanostructures (or called channel layers) 12 formed over the substrate 121, the inner spacer layers 14, the source/drain (S/D) structures 16, and the gate structure 18. The inner spacer layers 14 are adjacent to the nanostructures (or called channel layers) 12. In addition, the inner spacer layers 14 are between the gate structure 18 and the S/D structures 16. The inner spacer layers 14 are configured to separate the source/drain (S/D) structures 16 and the gate structures 18. The source/drain (S/D) structure or region(s) may refer to a source or a drain, individually or collectively dependent upon the context.

In some embodiments, the nanostructures 12 are made of semiconductor materials, such as Si or SiGe. In some embodiments, the inner spacer layers 14 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the S/D structures 16 are made of any applicable material, such as Ge, Si, GaAs, AlGaAs, SiGe, GaAsP, SiP, SiC, SiCP, or a combination thereof.

The gate structure 18 includes a gate dielectric layer and a gate electrode layer. The nanostructures 12 are surrounded by (e.g. wrapped in) the gate dielectric layer. In some embodiments, the gate dielectric layer includes one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al2O₃) alloy, another suitable high-k dielectric material, or a combination thereof. In some embodiments, the gate electrode layer includes one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof.

The substrate 121 and the substrate 122 may be a semiconductor wafer such as a silicon wafer. Alternatively or additionally, the substrate 121 and the substrate 122 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP. In some embodiments, the substrate 121 and the substrate 122 are made of silicon (Si) substrate.

In some embodiments, a number of conductive pads 124 are formed below the semiconductor die 120, and each of the conductive pads 124 is bonded to the conductive layer 126. Each of the conductive layers 126 is bonded to each of the conductive layers 116 through a number of conductive connectors 128.

The conductive pads 124 are made of metal materials, such as copper (Cu), copper alloy, aluminum (Al), aluminum alloy, tungsten (W), tungsten alloy, titanium (Ti), titanium alloy, tantalum (Ta) or tantalum alloy. In some embodiments, the conductive pad 124 is formed by an electroplating, electroless plating, printing, chemical vapor deposition (CVD) process or physical vapor deposition (PVD) process.

The conductive layers 126 are made of metal materials, such as copper (Cu), copper alloy, aluminum (Al), aluminum alloy, tungsten (W), tungsten alloy, titanium (Ti), titanium alloy, tantalum (Ta) or tantalum alloy. In some embodiments, the conductive layers 126 are formed by an electroplating, electroless plating, printing, a chemical vapor deposition (CVD) process, or a physical vapor deposition (PVD) process.

The conductive connector 128 is made of solder materials, such as tin (Sn), tin-silver (SnAg), tin-lead (SnPb), tin-copper (SnCu), tin-silver-copper (SnAgCu), tin-silver-zinc (SnAgZn), tin-zinc (SnZn), tin-bismuth-indium (SnBiIn), tin-indium (SnIn), tin-gold (SnAu), tin-zinc-indium (SnZnIn), tin-silver-Antimony (SnAgSb) or another applicable material. In some embodiments, the conductive connectors 128 are formed by electroplating, electroless plating, printing, a chemical vapor deposition (CVD) process, or a physical vapor deposition (PVD) process.

The stacked die 130 is disposed over the interconnect structure 110. The stacked die 130 is formed adjacent to the semiconductor die 120. The stacked die 130 includes a number of semiconductor dies 132A, 132B, 132C, 132D. In some embodiments, the semiconductor dies 132A, 132B, 132C, 132D are memory dies. The semiconductor die 120 has a different function from each of the plurality of the memory dies. The memory dies may include static random access memory (SRAM) devices, dynamic random access memory (DRAM) devices, high bandwidth memory (HBM) or another memory dies. The number of the semiconductor dies 132A, 132B, 132C, 132D are not limited to four, and the number can be adjusted according to the actual application.

The semiconductor dies 132A, 132B, 132C, 132D are stacked on a buffer die (or base die) 131 that performs as a logic circuit. The semiconductor dies 132A, 132B, 132C, 132D are bonded to each other by a number of bonding structures 136. A number of through substrate vias (TSVs) 134 are formed in the semiconductor dies 132A, 132B, 132C, 132D. The signal between the semiconductor dies 132A, 132B, 132C, 132D may be transferred through the through substrate vias (TSVs) 134 and the bonding structures 136.

Afterwards, an underfill layer 138 is formed between the semiconductor dies 132A, 132B, 132C, 132D to protect the bonding structures 136. In some embodiments, the underfill layer 138 includes an epoxy-based resin with fillers dispersed therein. The fillers may include insulating fibers, insulating particles, other suitable elements, or a combination thereof. A molding compound 140 protects the semiconductor dies 132A, 132B, 132C, 132D. In some embodiments, the molding compound 140 may include an epoxy-based resin with fillers dispersed therein. The fillers may include insulating fibers, insulating particles, other suitable elements, or a combination thereof. In some embodiments, the size and/or density of the fillers dispersed in the underfill layer 138 is smaller than those dispersed in the molding compound 140.

In some embodiments, a number of conductive pads 144 are formed on the stacked die 130, and each of the conductive pads 144 is bonded to the conductive layer 106 of the interconnect structure 110 through a conductive connector 146.

The conductive pads 144 are made of metal materials, such as copper (Cu), copper alloy, aluminum (Al), aluminum alloy, tungsten (W), tungsten alloy, titanium (Ti), titanium alloy, tantalum (Ta) or tantalum alloy. In some embodiments, the conductive pad 144 is formed by an electroplating, electroless plating, printing, chemical vapor deposition (CVD) process or physical vapor deposition (PVD) process.

The conductive connector 146 is made of solder materials, such as tin (Sn), SnAg, SnPb, SnAgCu, SnAgZn, SnZn, SnBiIn, SnIn, SnAu, SnPb, SnCu, SnZnIn, SnAgSb or another applicable material. In some embodiments, the conductive connector 146 is formed by electroplating, electroless plating, printing, chemical vapor deposition (CVD) process or physical vapor deposition (PVD) process.

Afterwards, as shown in FIG. 1C, an underfill layer 148 is formed between the semiconductor die 120, the stacked die 130 and the interconnect structure 110, in accordance with some embodiments of the disclosure. The underfill layer 148 surrounds and protects the conductive layers 126, the conductive connectors 128, the conductive pad 144 and the conductive connectors 146. In some embodiments, the underfill layer 148 is in direct contact with the conductive layers 126, the conductive connectors 128, the conductive pad 144 and the conductive connectors 146.

In some embodiments, the underfill layer 148 is made of or includes a polymer material. The underfill layer 148 may include an epoxy-based resin. In some embodiments, the underfill layer 148 includes fillers dispersed in the epoxy-based resin.

In some embodiments, the formation of the underfill layer 148 involves an injecting process, a spin-on process, a dispensing process, a film lamination process, an application process, or a combination thereof. In some embodiments, a thermal curing process is used during the formation of the underfill layer 148.

Afterwards, a first package layer 150 is formed over the underfill layer 148. The first package layer 150 is also formed over the substrate 122. There is an interface between the underfill layer 148 and the package layer 150, and the interface is lower than the top surface of the semiconductor die 120.

The first package layer 150 surrounds and protects the semiconductor dies 120 and the stacked dies 130. In some embodiments, the first package layer 150 is in direct contact with the semiconductor die 120 and the stacked die 130.

The first package layer 150 is made of a molding compound material. The molding compound material may include a polymer material, such as an epoxy-based resin with fillers dispersed therein. In some embodiments, a liquid molding compound material is applied over the semiconductor dies 120 and the stacked dies 130. The liquid molding compound material may flow into a space between the semiconductor dies 120 and the stacked dies 130. A thermal process is then used to cure the liquid molding compound material and to transform it into the first package layer 150. In some embodiments, the first package layer 150 is formed by compression molding process or transfer molding process, or another applicable process.

Afterwards, as shown in FIG. 1D, a portion of the first package layer 150 is removed to expose the top surface of the substrates 122 of the semiconductor dies 120, in accordance with some embodiments of the disclosure. In some embodiments, the portion of the first package layer 150 is removed by a planarization process, such as a chemical mechanical polishing (CMP) process.

Next, as shown in FIG. 1E, a carrier substrate 160 is formed over the package layer 150, and the substrate 102 is thinned from the back surface until the conductive layers 106 are exposed, in accordance with some embodiments of the disclosure. In other words, a portion of the interconnect structure 110 is removed. As a result, the conductive layers 106 of the interconnect structure 110 are exposed.

The carrier substrate 160 is configured to provide temporary mechanical and structural support during subsequent processing steps, in accordance with some embodiments. The carrier substrate 160 includes glass, silicon oxide, aluminum oxide, metal, a combination thereof, and/or the like, in accordance with some embodiments. The carrier substrate 160 includes a metal frame, in accordance with some embodiments.

Afterwards, a number of the conductive connectors 164 are formed over the exposed conductive layers 106 of the interconnect structure 110. The conductive connectors 164 are electrically connected to the conductive layers 106 of the interconnect structure 110. In some embodiments, the conductive connectors 164 are referred to as controlled collapse chip connection (C4) bumps. In some other embodiments, the conductive connectors 164 is micro bumps, electroless nickel-electroless palladium-immersion gold technique (ENEPIG) formed bumps, ball grid array (BGA) bumps, or the like.

Next, as shown in FIG. 1F, a second package layer 152 is formed on the first package layer 150, in accordance with some embodiments of the disclosure. As a result, an opening 153 is formed to expose the semiconductor die 120. The second package layer 152 is used as a wall or a barrier to prevent the first TIM 154 (formed later, as shown in FIG. 1F) from overflowing. Therefore, the height of the second package layer 152 is designed to be higher than the height of the first TIM 154.

More specifically, the second package layer 152 is directly formed on the stacked die 130. The second package layer 152 is vertically overlaps the stacked die 130. In some embodiments, the sidewall surface of the second package layer 152 is substantially aligned with the sidewall surface of the semiconductor die 120. The second package layer 152 is not formed on the semiconductor die 120.

In some embodiments, the second package layer 152 has a first height H₁ along the vertical direction. In some embodiments, the first height H₁ of the second package layer 152 is about 12 μm to about 120 μm. The first height H₁ of the second package layer 152 should be greater than the height of the first TIM 154 to have the function of wall. When the first height H₁ of the second package layer 152 is within the above-mentioned range, the heat dissipation efficiency is good.

The second package layer 152 may be the same as or different from the first package layer 150. The second package layer 152 is made of a molding compound material. The molding compound material may include a polymer material, such as an epoxy-based resin with fillers dispersed therein. In some embodiments, a liquid molding compound material is applied over the semiconductor die 130.

In some embodiments, the second package layer 152 is formed on the first package layer 150, not formed on the exposed semiconductor die 120 by using a fixture to make sure the sidewall surface of the second package layer 152 align with the sidewall surface of the semiconductor die 120. In some other embodiments, a protective layer (not shown) is formed on the exposed semiconductor die 120, and then the second package layer 152 is formed on the first package layer 150, and then the protective layer is removed.

Afterwards, as shown in FIG. 1G, a first thermal interface material (TIM) 154 is formed on the exposed semiconductor die 120, in accordance with some embodiments of the disclosure. The first TIM 154 is in direct contact with the semiconductor die 120. More specifically, the first TIM 154 is in direct contact with the substrate 122 of the semiconductor die 120. The top surface of the second package layer 152 is higher than the top surface of the first TIM 154. The overflow issue of the first TIM 154 can be reduced due to the height difference between the second package layer 152 and the semiconductor die 120.

During forming the first TIM 154, the first TIM 154 is formed in the opening 153, the first TIM 154 does not extends beyond the sidewall surface of the opening 153 by controlling the location of the nozzle for forming the material of the first TIM 154.

The first TIM 154 includes liquid metal and the liquid metal has a good thermal conductivity. Therefore, the heat generated from the semiconductor die 120 can be transferred to the external environment by the first TIM 154. In addition, the first TIM 154 includes silicone based gel, and the liquid metal (10%-45%) is in the silicone based gel. In some embodiments, the liquid metal of the first TIM 154 includes gallium (Ga) or gallium (Ga) alloy, bismuth (Bi), bismuth (Bi) alloy. The melting point of the gallium (Ga) is about 29° C., and that of gallium alloy is even lower. In some embodiment, the liquid metal is a liquid at room temperature. In some embodiments, the liquid metal of the first TIM 154 includes indium (In), tin (Sn) or zinc oxide (ZnO) or another applicable material.

Through-out the description, the term “liquid metal” refers to a metal or a metal alloy that may experience phase change to convert to a flowable form at a temperature higher than a threshold temperature. The liquid metal may have a higher viscosity at room temperature so that its flowability is low and is easy to apply.

The overflowing liquid metal of the first TIM 154 may have the possibility of electrically shorting some of features. Therefore, the second package layer 152 act as a wall to prevent the liquid metal of the first TIM 154 from overflowing.

In some embodiments, the sidewall surface of the first TIM 154 is substantially aligned with the sidewall surface of the semiconductor die 120. In some embodiments, the width of the sum of the two adjacent semiconductor die 120 is smaller than the width of the opening 153.

In some embodiments, the first TIM 154 has a second height H₂ along the vertical direction. In some embodiments, the second height H₂ of the first TIM 154 is in a range from about 10 μm to about 100 μm. The first height H₁ of the second package layer 152 is greater than the second height H₂ of the first TIM 154.

Next, as shown in FIG. 1H, a second TIM 158 is formed on the semiconductor die 120, in accordance with some embodiments of the disclosure. As a result, the top surface of the second TIM 158 is higher than the top surface of the first TIM 154. In some embodiments, the sidewall surface of the first TIM 154 is substantially aligned with the sidewall surface of the second TIM 158.

The material of the second TIM 158 is different from the material of the first TIM 154. In some embodiments, the thermal conductivity of the first TIM 154 is greater than the thermal conductivity of the second TIM 158. In some embodiments, the thermal conductivity of the first TIM 154 is in a range from about 6 W/mK to about 15 W/mK. In some embodiments, the thermal conductivity of second TIM 158 is in a range from about 3 W/mK to about 6 W/mK. In addition, the fluidity of the first TIM 154 is greater than the fluidity of the second TIM 158 since the first TIM 154 includes liquid metal.

In some embodiments, the second TIM 158 includes aluminum (Al) or zinc oxide (ZnO) or another applicable material. In some embodiments, the second TIM 158 includes aluminum oxide, boron nitride, aluminum nitride, aluminum, copper, silver, indium, a combination thereof, or another applicable material. In some embodiments, the second TIM 158 includes a polymer material. In some embodiments, the second TIM 158 includes other materials, such as a metallic-based or solder-based material comprising silver, indium paste, or another applicable material. In some other embodiments, the second TIM 158 includes a film-based or sheet-based material, such as a sheet-based material including synthesized carbon nanotubes (CNTs) or a thermally conductive sheet having vertically oriented graphite fillers. In some embodiments, the formation sequence of the first TIM 154 and the second TIM 158 can be changed. In some embodiments, the first TIM 154 is formed before the second TIM 158 is formed. In some other embodiments, the first TIM 154 is formed after the second TIM 158 is formed.

Afterwards, as shown in FIG. 1I, the package structure 100a is bonded to a package substrate 170 through the conductive connectors 164, in accordance with some embodiments.

In some embodiments, the package substrate 170 is a printed circuit board (PCB), a ceramic substrate or another suitable package substrate. The interconnect structure 110 is used as fan out electrical connection to connect the signals of the semiconductor die 120, the stacked die 130 to the package substrate 170.

Next, as shown in FIG. 1J, a lid structure 172 is formed over the first TIM 154 and the second TIM 158, in accordance with some embodiments of the disclosure. A number of the conductive connectors 176 are formed below the package substrate 170. After the lid structure 172 is formed over the first TIM 154 and the second TIM 158, a thermal curing process is performed to cure the first TIM 154 and the second TIM 158. After the thermal curing process, the first TIM 154 still have fluidity due to the liquid metal, and the second TIM 158 becomes solid.

The heat generated from the semiconductor die 120, the stacked die 130 dissipate to the lid structure 172, and then dissipate to the external environment. The lid structure 172 is attached to the package substrate 170 by an adhesive 174.

The lid structure 172 has a main portion 172a, leg portions 172b and an extending portion 172c. The leg portions 172b extends from the main portion 172a to connect the adhesive 174. The extending portion 172c extends from the main portion 172a to connect the first TIM 154. The extending portion 172c of the lid structure 172 is in direct contact with the first TIM 154 to help the heat dissipation. The extending portion 172c of the lid structure 172 is in direct contact with the interface between the second package layer 152 and the second TIM 158.

The main portion 172a of the lid structure 172 is in direct contact with the second TIM 158, and the extending portion 172c of the lid structure 172 is in direct contact with the first TIM 154. The first interface between the extending portion 172c of the lid structure 172 and the first TIM 154 is lower than the second interface between the main portion 172a of the lid structure 172 and the second TIM 158.

In some embodiments, the lid structure 172 has a high thermal conductivity, for example, between about 200 W/mK to about 400 W/mK. In some embodiments, the lid structure 172 is made of copper (Cu), copper alloy, copper tungsten (CuW), or aluminum-silicon-carbide (AlSiC) or another applicable material. In some embodiments, the adhesive 174 is made of polymer having a good thermal conductivity.

The conductive connectors 176 are made of solder materials, such as tin (Sn), SnAg, SnPb, SnAgCu, SnAgZn, SnZn, SnBiIn, SnIn, SnAu, SnPb, SnCu, SnZnIn, SnAgSb or another applicable material. In some embodiments, the conductive connector 146 is formed by electroplating, electroless plating, printing, a chemical vapor deposition (CVD) process or a physical vapor deposition (PVD) process.

In a compared embodiment, all of the top surfaces of the semiconductor dies 120 and the stacked dies 130 covered with the first TIM 154, the liquid metal may have overflow issue. In order to prevent overflow, the height difference between the top surface of the second package layer 152 and the top surface of the semiconductor die 120 is formed to prevent the liquid metal of the first TIM 154 from flowing out.

It should be noted that, the semiconductor dies 120 are high power consumption dies, and the stacked dies 130 are low power consumption dies compared with the semiconductor dies 120. The mainly hot spots are located at the semiconductor dies 120. Therefore, the first TIM 154 with good thermal conductivity can transfer the heat more efficiently. Since the power consumption difference between the semiconductor dies 120 and the stacked dies 130, the first TIM 154 is directly formed on the semiconductor dies 120, and the second TIM 158 is directly formed on the stacked dies 130. The amount or usage of the first TIM 154 is reduced compared with the compared embodiment, and the cost is further reduced. Therefore, the heat dissipation efficiency is improved and the cost of the package structure 100a is reduced.

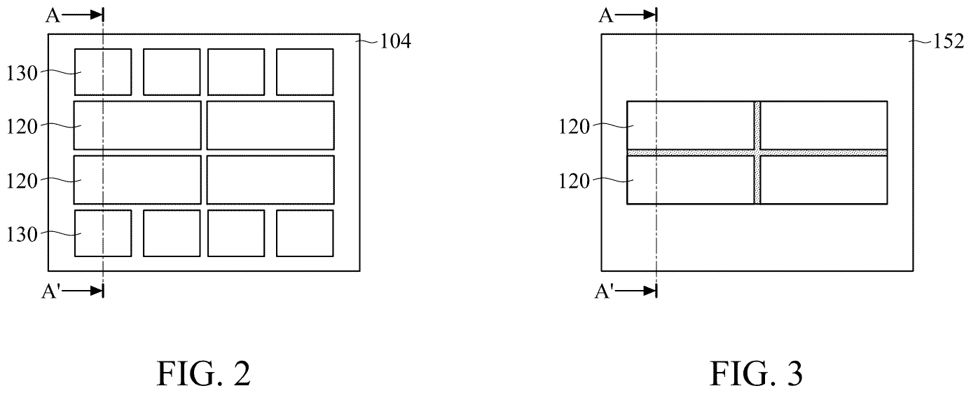

FIG. 2 shows a top view of the semiconductor dies 120 and the stacked dies 130 of FIG. 1B, in accordance with some embodiments of the disclosure. FIG. 1B shows the cross-sectional representation of the package structure 100a along the AA′ line of FIG. 2.

The stacked dies 130 are formed adjacent to the semiconductor dies 120. The four semiconductor dies 120 are surrounded by the eight the stacked dies 130. The number of the semiconductor dies 120 and the stacked dies 130 can be adjusted according to the actual application.

FIG. 3 shows a top view of the semiconductor dies 120 and the stacked dies 130 of FIG. 1E, in accordance with some embodiments of the disclosure. FIG. 1E shows the cross-sectional representation of the package structure 100a along the AA′ line of FIG. 3.

After the second package layer 152 is formed on the stacked dies 130, the stacked dies 130 are covered by the second package layer 152. Therefore, the semiconductor dies 120 are exposed.

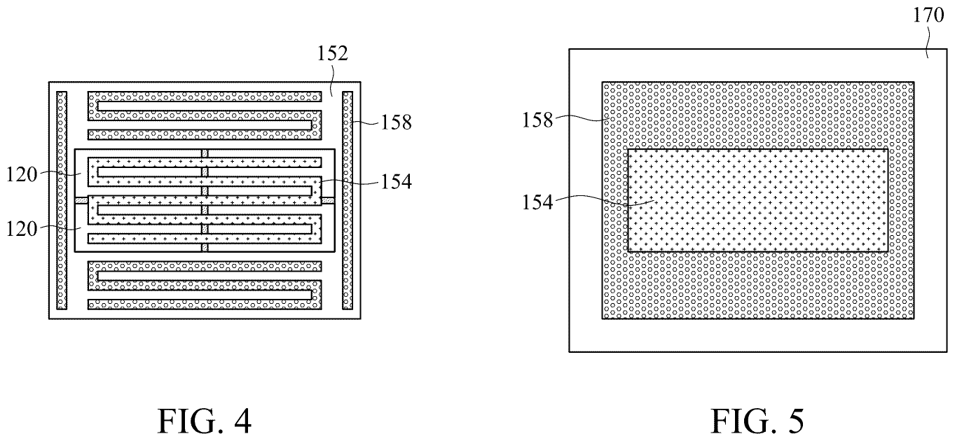

FIG. 4 shows a top view of the initial pattern of the first TIM 154 and the second TIM 158 of FIG. 1G, in accordance with some embodiments of the disclosure. Before the curing process, the first TIM 154 is directly formed on the semiconductor dies 120, and does not flow to the stacked dies 130 since the second package layer 152 is higher than the top surface of the semiconductor dies 120. In addition, the second TIM 158 is directly formed on the second package layer 152.

The first TIM 154 have a rectangular shape when seen from a top-view. In some embodiments, the first TIM 154 have concentric circles shape when seen from a top-view. The second TIM 158 have a rectangular shape when seen from a top-view. In some embodiments, the second TIM 158 have concentric circles shape when seen from a top-view. The initial pattern of the first TIM 154 and the second TIM 158 can be adjusted according to actual application.

FIG. 5 shows a top view of the final pattern of the first TIM 154 and the second TIM 158 of FIG. 1J, in accordance with some embodiments of the disclosure. The lid structure 172 of FIG. 1J is not shown for clarity.

After the curing process, the first TIM 154 is uniformly distributed on the semiconductor dies 120, and the second TIM 158 is uniformly distributed on the second package layer 152. The first TIM 154 is surrounded by the second TIM 158.

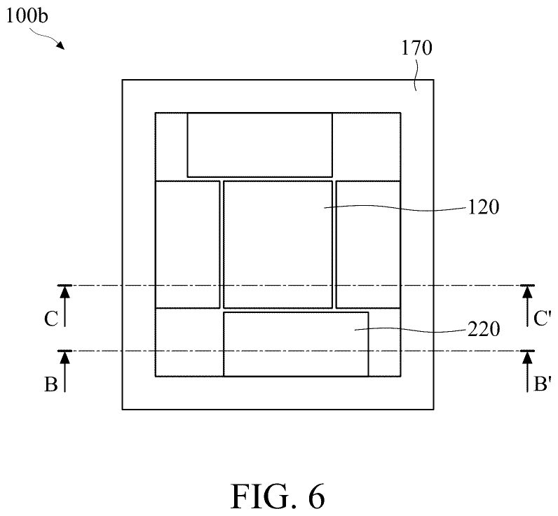

FIG. 6 shows a top view of a package structure 100b, in accordance with some embodiments of the disclosure. The package structure 100b is similar to, or the same as, the package structure 100a shown in FIGS. 1A-1J. Processes and materials used to form semiconductor device structure 100b may be similar to, or the same as, those used to form the semiconductor device structure 100a and a detailed description thereof is not repeated herein.

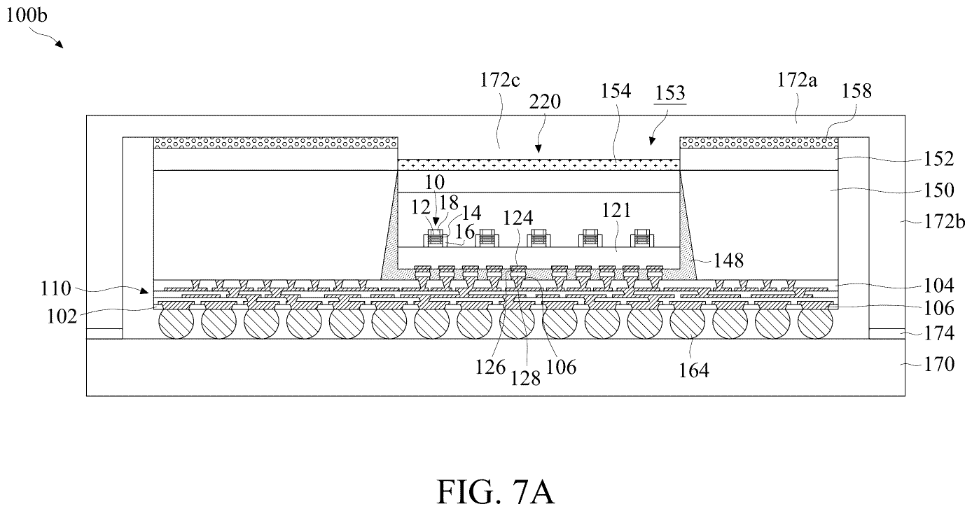

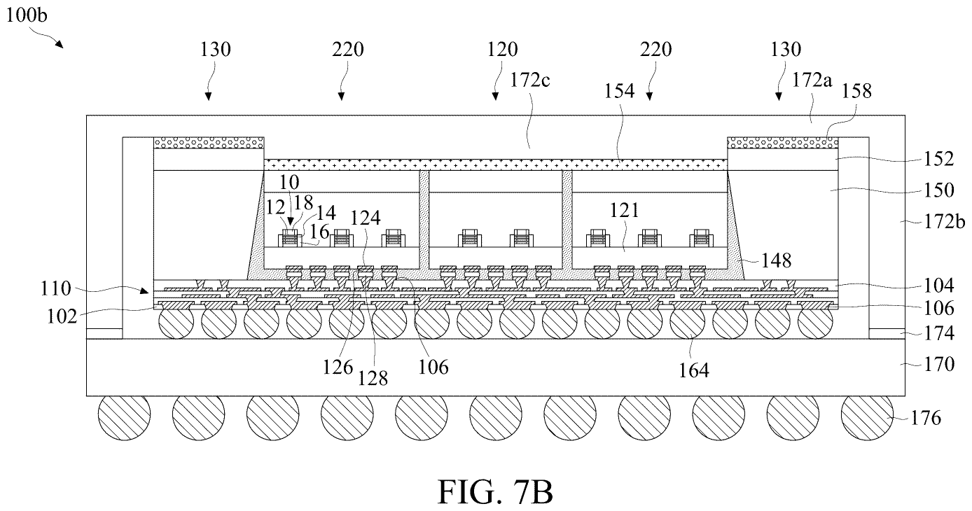

FIG. 7A shows a cross-sectional representation of the package structure 100b along the BB′ line of FIG. 6, in accordance with some embodiments of the disclosure. FIG. 7B shows a cross-sectional representation of the package structure 100b along the CC′ line of FIG. 6, in accordance with some embodiments of the disclosure.

As shown in FIGS. 6, 7A and 7B, the semiconductor dies 220 and the semiconductor die 120 are formed on the substrate 102, in accordance with some embodiments of the disclosure. One semiconductor die 120 is surrounded by the four semiconductor dies 220. The number and the layout of the semiconductor dies 220 and the semiconductor die 120 can be adjusted according to actual application.

The function of the semiconductor dies 220 is different from the function of the semiconductor dies 120. Both of the semiconductor dies 220 and the semiconductor dies 120 are high power consumption dies, and therefore the first TIM 154 is formed on the top surfaces of both the semiconductor dies 220 and the semiconductor dies 120.

Each of the semiconductor die 220 also has a substrate 121, a semiconductor structure 10 formed on the substrate 102, and a substrate 122 formed on the semiconductor structure 10. In some embodiments, the semiconductor structure 10 is a logic device. In some embodiments, the semiconductor structure 10 is a gate all around (GAA) transistor structure. In some embodiments, the logic devices are Central Processing Unit (CPU) dies, Graphic Processing Unit (GPU) dies, mobile application dies, Micro Control Unit (MCU) dies, BaseBand (BB) dies, Application processor (AP) dies, or the like.

The semiconductor structure 10 includes nanostructures (or called channel layers) 12 formed over the substrate 121, the inner spacer layers 14, the source/drain (S/D) structures 16, and the gate structure 18. The inner spacer layers 14 are adjacent to the nanostructures (or called channel layers) 12. In addition, the inner spacer layers 14 are between the gate structure 18 and the S/D structures 16. The inner spacer layers 14 are configured to separate the source/drain (S/D) structures 16 and the gate structures 18.

The second package layer 152 is formed on the first package layer 150 to create the height difference, and the first TIM 154 does not overflow due to the height difference. The second TIM 158 is formed on the second package layer 152, and the top surface of the second TIM 158 is higher than the top surface of the first TIM 154. Due to the height differences, the overflow issue of the liquid metal of the first TIM 154 can be reduced, and therefore the heat dissipation efficiency of the package structure 100b can be improved.

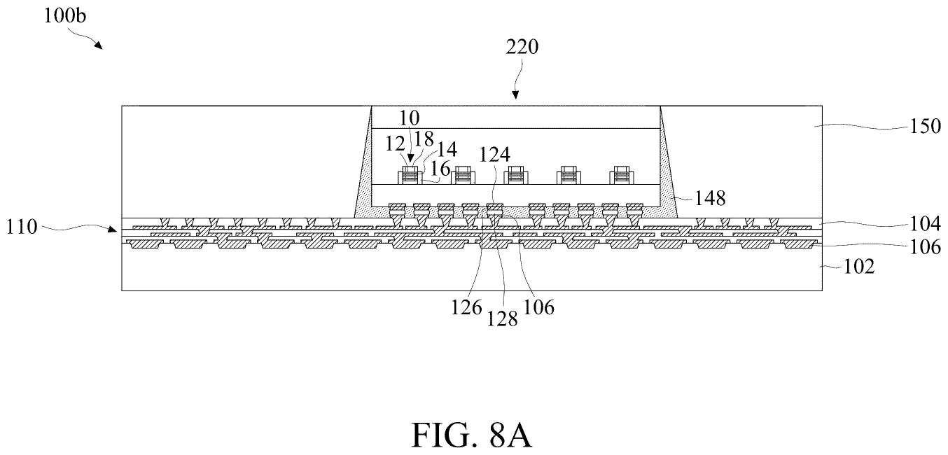

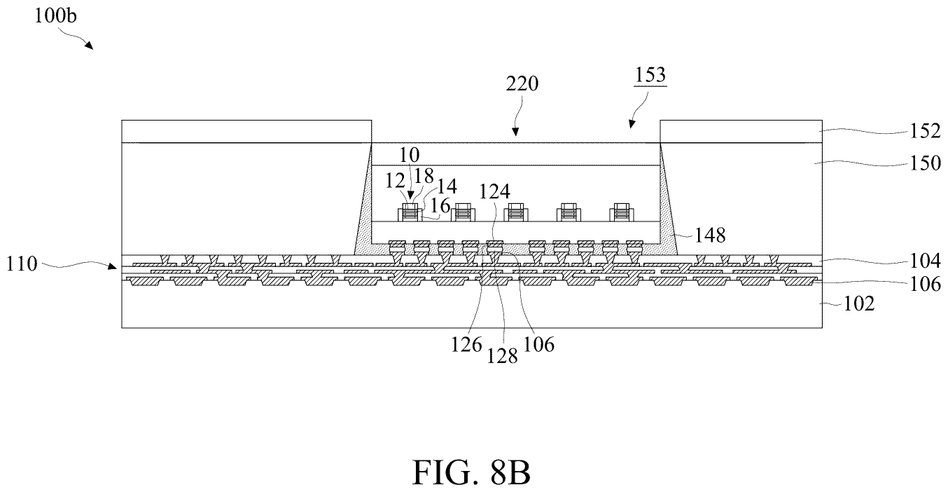

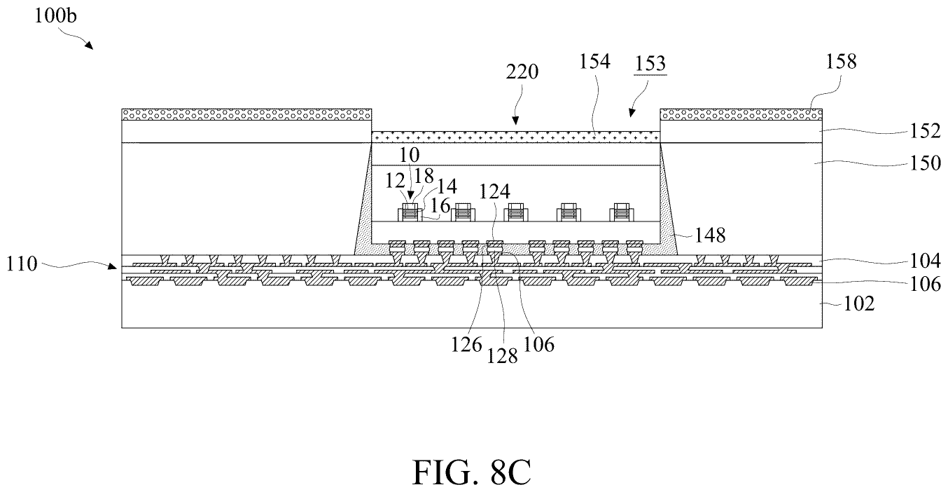

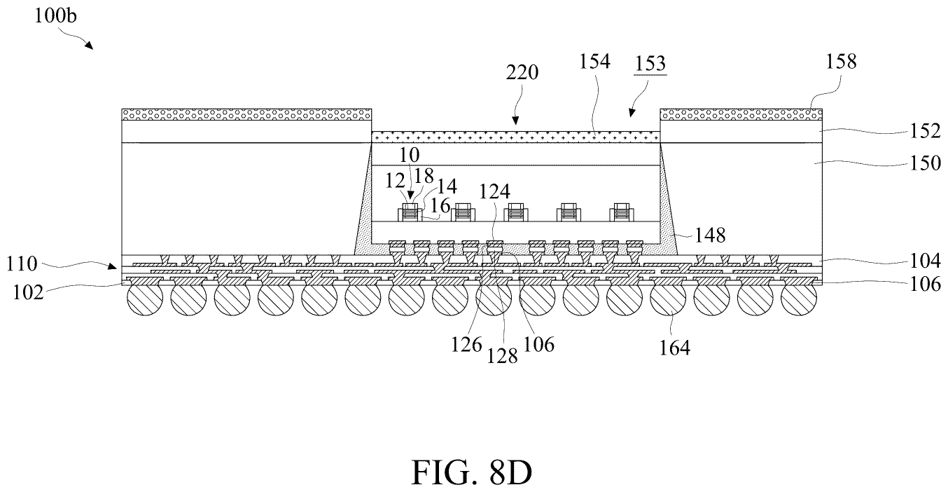

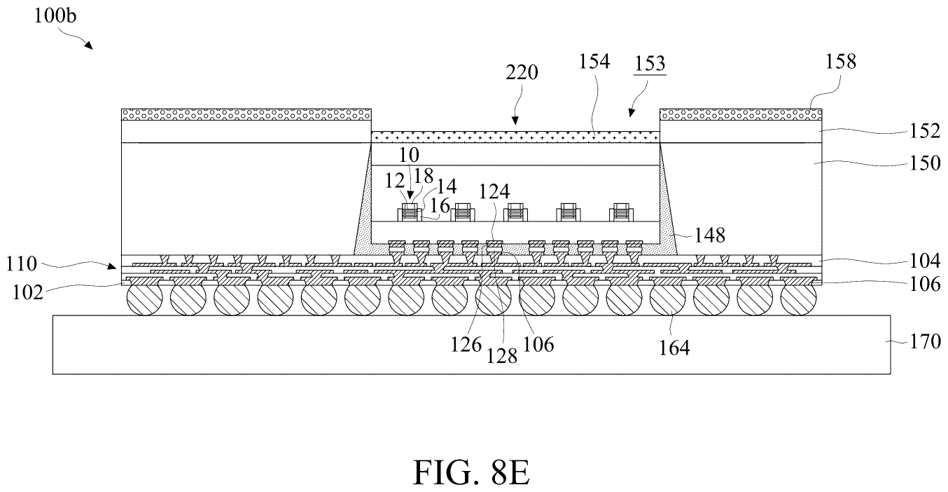

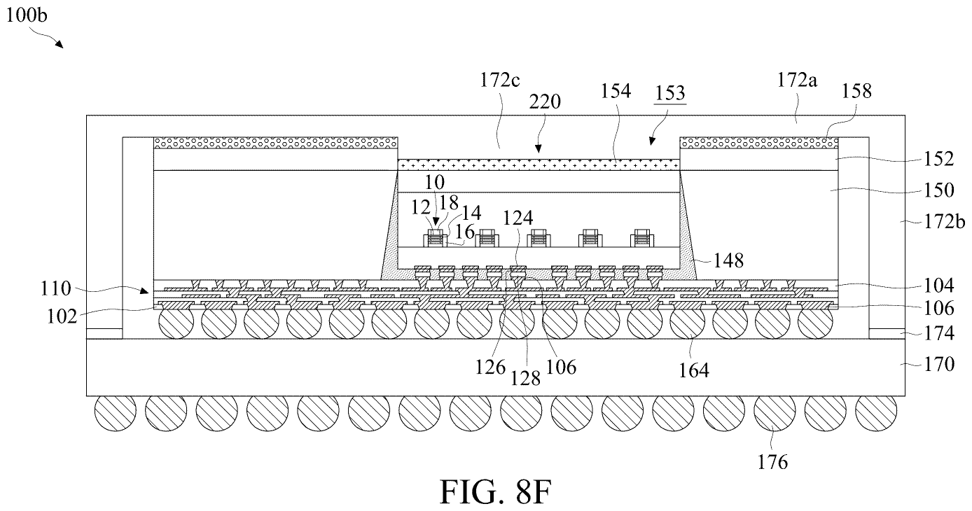

FIG. 8A-8F shows a cross-sectional representation of the package structure 100b, in accordance with some embodiments of the disclosure. Processes and materials used to form semiconductor device structure 100b may be similar to, or the same as, those used to form the semiconductor device structure 100a and a detailed description thereof is not repeated herein.

As shown in FIG. 8A, the semiconductor die 220 are formed over the substrate 102, and the underfill layer 148 is formed to surround the semiconductor die 220. Next, the first package layer 150 is formed on the underfill layer 148.

Afterwards, as shown in FIG. 8B, the second package layer 152 is formed on the first package layer 150, in accordance with some embodiments of the disclosure. The height difference is created by forming the second package layer 152 higher than the top surface of the semiconductor die 220. The top surface of the semiconductor die 220 is exposed by the opening 153.

Next, as shown in FIG. 8C, the first TIM 154 is formed on the exposed semiconductor die 220, and the second TIM 158 is formed on the second package layer 152, in accordance with some embodiments of the disclosure. The top surface of the second TIM 158 is higher than the top surface of the first TIM 154.

The material of the second TIM 158 is different from the material of the first TIM 154. In some embodiments, the thermal conductivity of the first TIM 154 is greater than the thermal conductivity of the second TIM 158. In addition, the fluidity of the first TIM 154 is greater than the fluidity of the second TIM 158 since the first TIM 154 includes liquid metal.

Afterwards, as shown in FIG. 8D, a portion of the interconnect structure 110 is removed, in accordance with some embodiments of the disclosure. As a result, the conductive layer 106 of the interconnect structure 110 is exposed.

Afterwards, a number of the conductive connectors 164 are formed over the exposed conductive layer 116 of the interconnect structure 110. The conductive connectors 164 are electrically connected to the conductive layers 116 of the interconnect structure 110. In some embodiments, the conductive connectors 164 are referred to as controlled collapse chip connection (C4) bumps. In some other embodiments, the conductive connectors 164 is micro bumps, electroless nickel-electroless palladium-immersion gold technique (ENEPIG) formed bumps, ball grid array (BGA) bumps, or the like.

Next, as shown in FIG. 8E, the package structure 100b is bonded to the package substrate 170 through the conductive connectors 164, in accordance with some embodiments.

In some embodiments, the package substrate 170 is a printed circuit board (PCB), a ceramic substrate or another suitable package substrate. The interconnect structure 110 is used as fan out electrical connection to connect the signals of the semiconductor die 120, the stacked die 130 to the package substrate 170.

Next, as shown in FIG. 8F, the lid structure 172 is formed over the first TIM 154 and the second TIM 158, in accordance with some embodiments of the disclosure. A number of the conductive connectors 176 are formed below the package substrate 170. Accordingly, the heat generated from the semiconductor die 120, the stacked die 130 may dissipate to the lid structure 172, and then dissipate to the external environment. The lid structure 172 is attached to the package substrate 170 by the adhesive 174.

The lid structure 172 has the main portion 172a, leg portions 172b and the extending portion 172c. The leg portions 172b extends from the main portion 172a to connect the adhesive 174. The extending portion 172c extends from the main portion 172a to connect the first TIM 154. The extending portion 172c of the lid structure 172 is in direct contact with the first TIM 154 to help the heat dissipation. The extending portion 172c of the lid structure 172 is in direct contact with the interface between the second package layer 152 and the second TIM 158. The first interface between the extending portion 172c of the lid structure 172 and the first TIM 154 is lower than the second interface between the main portion 172a of the lid structure 172 and the second TIM 158.

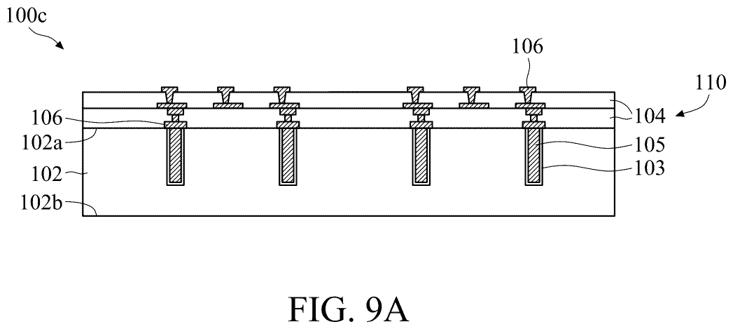

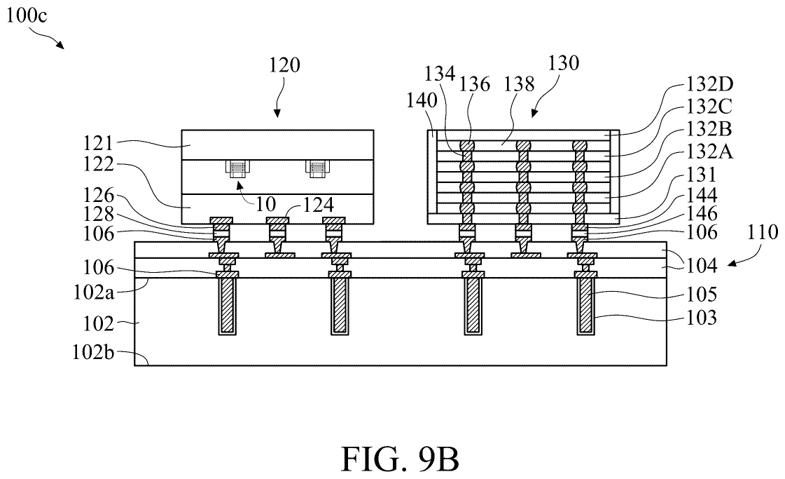

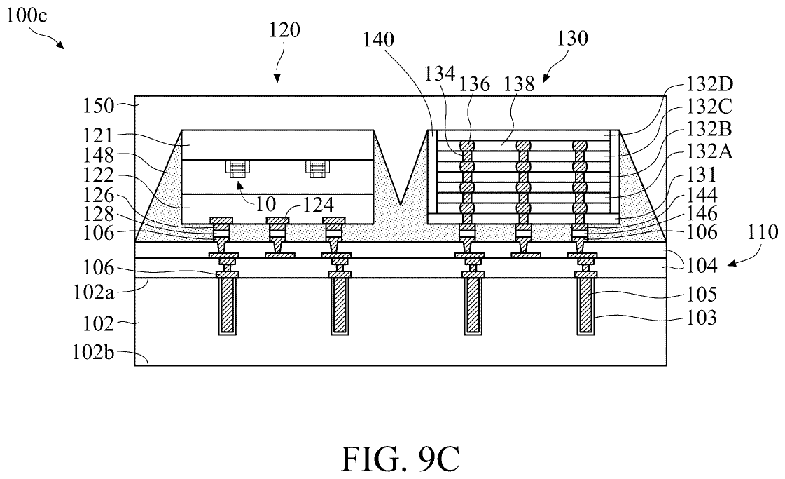

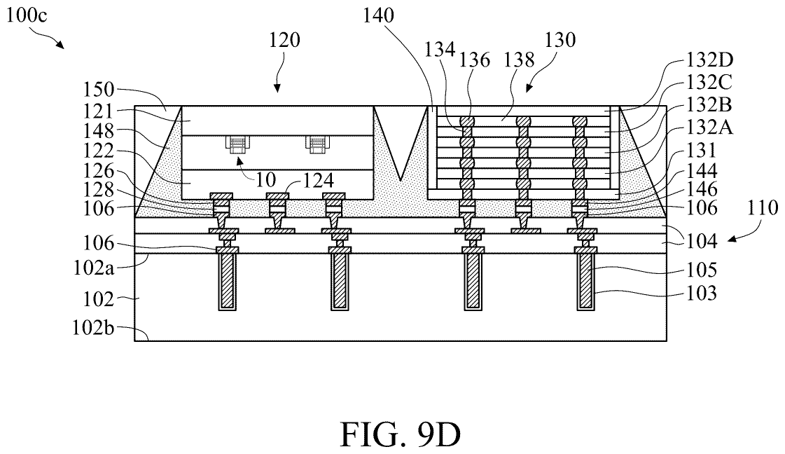

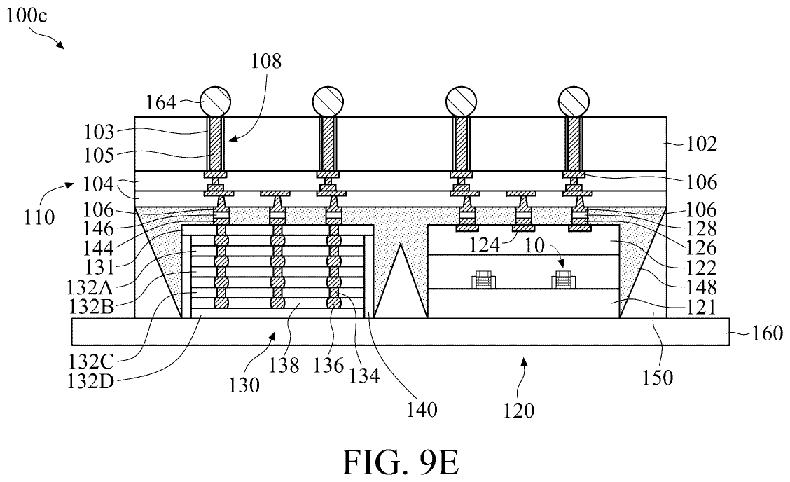

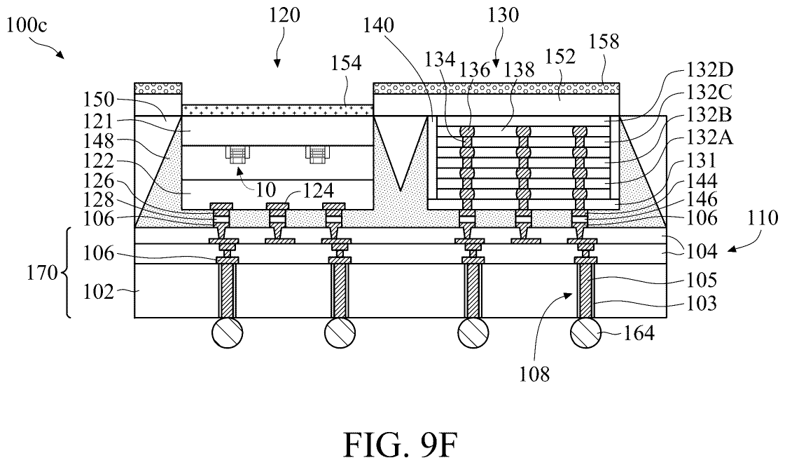

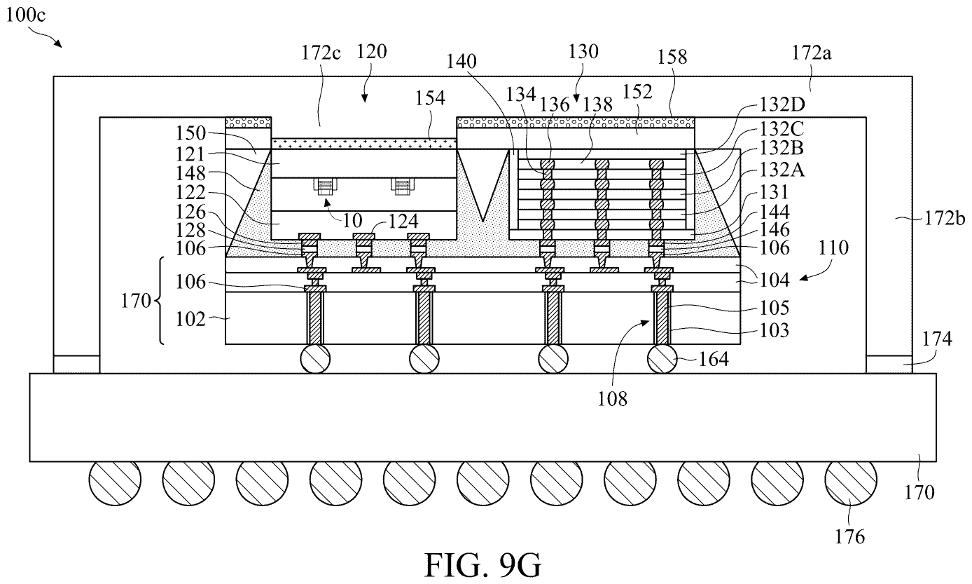

FIGS. 9A-9G shows a cross-sectional representation of a package structure 100c, in accordance with some embodiments of the disclosure. Processes and materials used to form semiconductor device structure 100c may be similar to, or the same as, those used to form the semiconductor device structure 100a and a detailed description thereof is not repeated herein.

As shown in FIG. 9A, the conductive structures 105 are formed in the substrate 102. The conductive structures 105 extend from the front surface 102a of the substrate 102 towards the back surface 102b of the substrate 102. In some embodiments, the conductive structures 105 are formed by forming a number of trenches (not shown) which extend from the front surface 102a of the substrate 102. Afterwards, a barrier layer 103 is filled into each of the trenches, and the conductive structure 105 is formed on the barrier layer 103 and in each of the trenches.

The interconnect structure 110 is formed over the conductive structures 105 and the substrate 102. The interconnect structure 110 may be used as a redistribution (RDL) structure for routing. The interconnect structure 110 includes multiple conductive layers 106 formed in multiple dielectric layers 104. In some embodiments, the conductive layers 106 are exposed at or protruding from the top surface of the top of the dielectric layers 104 to serve as bonding pads.

The conductive structure 105 and the conductive layers 106 may be made of copper (Cu), copper alloy, aluminum (Al), aluminum alloy, tungsten (W), tungsten alloy, titanium (Ti), titanium alloy, tantalum (Ta) or tantalum alloy. In some embodiments, the conductive structures 105 and the conductive layers 106 are formed by an electroplating, electroless plating, printing, a chemical vapor deposition (CVD) process, or a physical vapor deposition (PVD) process.

Afterwards, as shown in FIG. 9B, the semiconductor dies 120 and the stacked die 130 are formed over the conductive layer 106, in accordance with some embodiments of the disclosure. The semiconductor die 120 includes the substrate 121 and the semiconductor structure 10 over the substrate 121.

The semiconductor structure 10 includes nanostructures (or called channel layers) 12 formed over the substrate 121, the inner spacer layers 14, the source/drain (S/D) structures 16, and the gate structure 18. The inner spacer layers 14 are between the nanostructures 12 and the S/D structures 16.

In some embodiments, the semiconductor dies 120 is sawed from a wafer, and may be a “known-good-die”. The first semiconductor die 120 may be a system-on-chip (SoC) chip or memory die.

In some embodiments, a number of conductive layers 126 are formed below the conductive pads 124 of the semiconductor dies 120, and each of the conductive layers 126 is bonded to each of the conductive layers 106 through a number of conductive connectors 128.

The stacked die 130 is disposed over the interconnect structure 110. The stacked die 130 is formed adjacent to the semiconductor die 120. The stacked die 130 includes a number of semiconductor dies 132A, 132B, 132C, 132D. In some embodiments, the semiconductor dies 132A, 132B, 132C, 132D are memory dies. The semiconductor die 120 has a different function from each of the plurality of the memory dies. The memory dies may include static random access memory (SRAM) devices, dynamic random access memory (DRAM) devices, high bandwidth memory (HBM) or another memory dies. The number of the semiconductor dies 132A, 132B, 132C, 132D are not limited to four, and the number can be adjusted according to the actual application.

Afterwards, as shown in FIG. 9C, the underfill layer 148 is formed between the semiconductor die 120, the tacked die 130 and the interconnect structure 110, in accordance with some embodiments of the disclosure. The underfill layer 148 surrounds and protects the conductive connectors 146 and the conductive connectors 128. In some embodiments, the underfill layer 148 is in direct contact with the conductive conductors 146 and the conductive connectors 128.

Afterwards, the first package layer 150 is formed over the underfill layer 148. The first package layer 150 is also formed over the substrate 122. The first package layer 150 surrounds and protects the semiconductor die 120 and the stacked die 130. In some embodiments, the first package layer 150 is in direct contact with a portion of the semiconductor die 120 and the stacked die 130.

Next, as shown in FIG. 9D, a portion of the first package layer 150 is removed to expose the top surface of the substrate 121, in accordance with some embodiments of the disclosure. In some embodiments, the portion of the first package layer 150 is removed by a planarization process, such as a chemical mechanical polishing (CMP) process.

Afterwards, as shown in FIG. 9E, the carrier substrate 160 is formed over the substrate 121 and the first package layer 150, and the structure as shown in FIG. 9D is flipped, in accordance with some embodiments of the disclosure. Next, the substrate 102 is thinned from the back surface 102b until the conductive structures 105 are exposed. In some embodiments, the conductive structures 105 and the barrier layer 103 become exposed and penetrate through the thinned substrate 102. As a result, the through via structures 108 are formed in the substrate 102. In some embodiments, the through via structures 108 are through substrate via (TSV) structures.

Afterwards, a number of the conductive connectors 164 are formed over the through via structures 108. In some embodiments, the conductive connectors 164 are referred to as controlled collapse chip connection (C4) bumps. In some other embodiments, the conductive connectors 164 is micro bumps, electroless nickel-electroless palladium-immersion gold technique (ENEPIG) formed bumps, ball grid array (BGA) bumps, or the like.

Next, as shown in FIG. 9F, the structure as shown in FIG. 9E is flipped and the carrier substrate 160 is removed to expose the top surface of the substrate 121, in accordance with some embodiments of the disclosure. As a result, an interposer 170 is obtained. The interposer 170 includes the through via structures 108 in the substrate 102 and the interconnect structure 110 electrically connected to the through via structures 108. The semiconductor dies 120 and the stacked die 130 are electrically connected to the conductive connectors 164 by the interposer 170.

Next, the second package layer 152 is formed on the first package layer 150 to expose the stacked die 130. The first TIM 154 is formed on the exposed stacked die 130, and the second TIM 158 is formed on the second package layer 152. The top surface of the second package layer 152 is higher than the top surface of semiconductor dies 120. The second package layer 152 is used as a wall or barrier to prevent the first TIM 154 from being overflowing. In some embodiments, the formation sequence of the first TIM 154 and the second TIM 158 can be changed. In some embodiments, the first TIM 154 is formed before the second TIM 158 is formed. In some other embodiments, the first TIM 154 is formed after the second TIM 158 is formed.

Afterwards, as shown in FIG. 9G, the lid structure 172 is formed over the first TIM 154 and the second TIM 158, in accordance with some embodiments of the disclosure. A number of the conductive connectors 176 are formed below the package substrate 170. Accordingly, the heat generated from the semiconductor die 120, the stacked die 130 may dissipate to the lid structure 172, and then dissipate to the external environment. The lid structure 172 is attached to the package substrate 170 by an adhesive 174.

The lid structure 172 has a main portion 172a, leg portions 172b and an extending portion 172c. The leg portions 172b extends from the main portion 172a to connect the adhesive 176. The extending portion 172c extends from the main portion 172a to connect the first TIM 154. The extending portion 172c of the lid structure 172 is in direct contact with the first TIM 154 to help the heat dissipation.

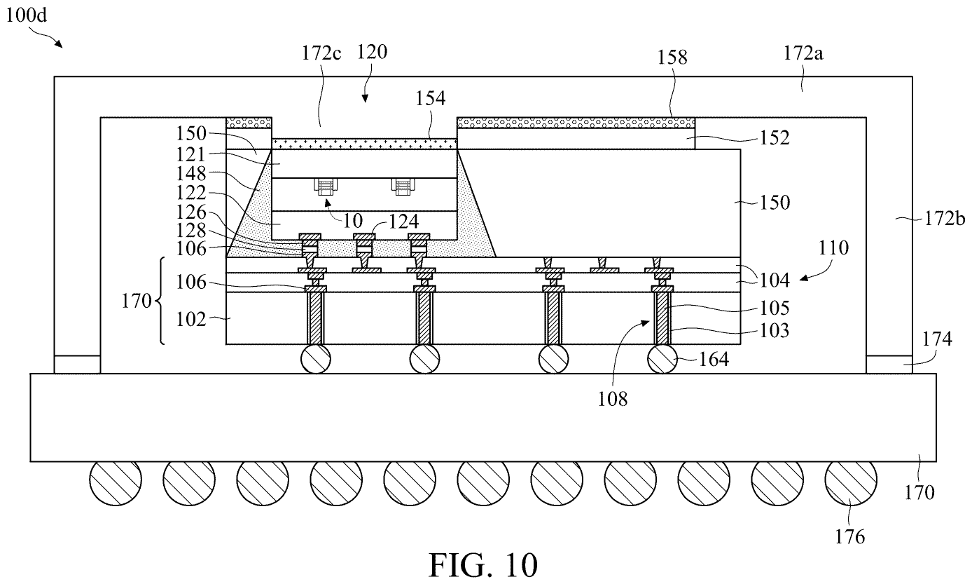

FIG. 10 shows a cross-sectional representation of a package structure 100d, in accordance with some embodiments of the disclosure. Processes and materials used to form semiconductor device structure 100d may be similar to, or the same as, those used to form the semiconductor device structure 100c and a detailed description thereof is not repeated herein.

The difference between FIG. 10 and FIG. 9G is that the second package layer 152 is formed on the first package layer 150, and no stacked die is formed directly below the second package layer 152.

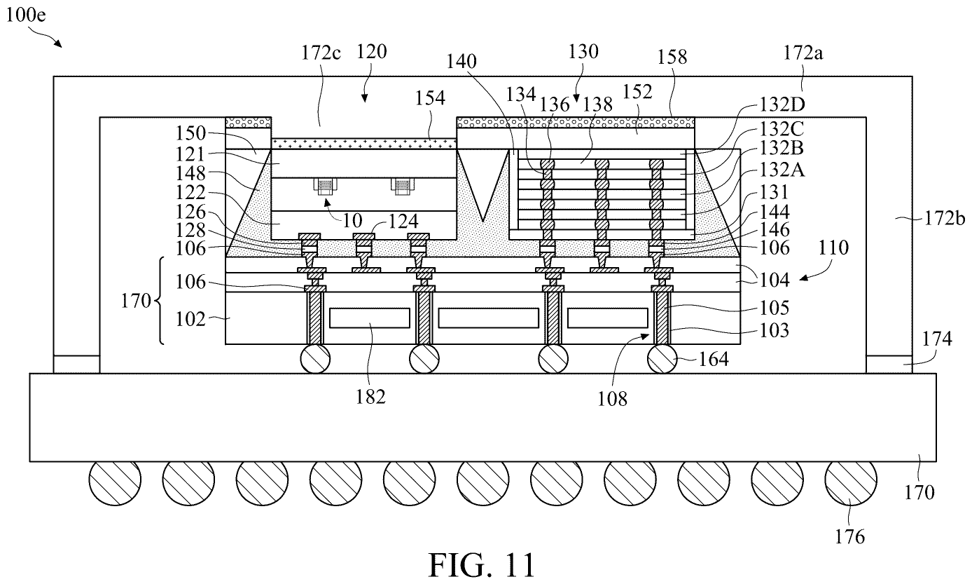

FIG. 11 shows a cross-sectional representation of a package structure 100e, in accordance with some embodiments of the disclosure. Processes and materials used to form semiconductor device structure 100e may be similar to, or the same as, those used to form the semiconductor device structure 100c and a detailed description thereof is not repeated herein.

The difference between FIG. 11 and FIG. 9G is that local silicon interconnect (LSI) dies 182 are formed in the substrate 102. The LSI dies 182 may be encapsulated in an encapsulant. A number of Through-vias (not shown) may be formed to penetrate through the encapsulant.

By using liquid metal in the first TIM 154, and using polymer in the second TIM 158, the composite TIM with two different thermal conductivity and two different fluidity is used to improve the heat dissipation. The first TIM 154 is directly formed on the semiconductor die 120 with high power consumption, and the second TIM 158 is directly formed on the stacked die 130 with low power consumption. The composite TIMs are formed at different regions to improve the heat-dissipation efficiency.

Since the power consumption difference of the semiconductor dies 120 and the stacked dies 130, the first TIM 154 is directly formed on the semiconductor dies 120, and the second TIM 158 is directly formed on the stacked dies 130. The amount or usage of the first TIM 154 is reduced. Therefore, the heat dissipation efficiency is improved and the cost of the package structure is reduced.

The second package layer 152 is directly formed on the stacked die 130, not formed on the semiconductor die 120 or the semiconductor die 220, the height difference is created. Due to the height differences, the overflow issue of the liquid metal of the first TIM 154 can be reduced, and therefore the heat dissipation efficiency of the package structure 100b can be improved.

Furthermore, the terms “approximately,” “substantially,” “substantial” and “about” describe above account for small variations and may be varied in different technologies and be in the deviation range understood by the skilled in the art. For example, when used in conjunction with an event or circumstance, the terms can refer to instances in which the event or circumstance occurs precisely as well as instances in which the event or circumstance occurs to a close approximation.

Embodiments for forming a package structure and method for formation the same are provided. The package structure includes a first die and a second die formed over a substrate. A first package layer surrounds the first die and the second die. A second package layer formed on the first package layer, not on the first die to create a height difference. The first TIM is formed on the first die and includes liquid metal. A second TIM is formed on the second package layer. A lid structure is formed on the first TIM and the second TIM. The height difference between the top surface of the second package layer and the top surface of the first TIM is formed to prevent the liquid metal of the first TIM from flowing out. Therefore, the overflowing issue of the first TIM is resolved. In addition, the heat dissipation efficiency and the performance of the package structure are improved.

In some embodiments, a package structure is provided. The package structure includes a first die formed over a substrate, and a first package layer surrounding the first die. The package structure includes a lid structure formed over the first die and the package layer and a first thermal interface material (TIM) formed between the first die and the lid structure. The first thermal interface material comprises liquid metal. The package structure includes a second TIM formed between the first package layer and the lid structure, and a top surface of the second TIM is higher than a top surface of the first TIM.

In some embodiments, a package structure is provided. The package structure includes a first die formed over a substrate, and a first package layer surrounding the first die. The package structure includes a first thermal interface material (TIM) formed on the first die, and the first TIM comprises liquid metal. The package structure includes a lid structure formed on the first TIM, and the lid structure comprises an extending portion which is in direct contact with the first TIM.

In some embodiments, a method for forming a package structure is provided. The method includes forming a first die on a substrate, and forming a first package layer surrounding the first die. The method includes forming a second package layer on the first package layer to expose the first die, and forming a first thermal interface material (TIM) on the first die. The first TIM comprises liquid metal. The method includes forming a second TIM on the second package layer, and a top surface of the second TIM is higher than a top surface of the first TIM.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a first die formed over a substrate;
a first package layer surrounding the first die;
a lid structure formed over the first die and the package layer;
a first thermal interface material (TIM) between the first die and the lid structure, wherein the first thermal interface material comprises liquid metal; and
a second TIM between the first package layer and the lid structure, wherein a top surface of the second TIM is higher than a top surface of the first TIM.

2. The package structure as claimed in claim 1, further comprising:
a second die formed adjacent to the first die, wherein the second TIM is directly formed on the second die.

3. The package structure as claimed in claim 1, wherein the first die comprises:
a plurality of nanostructures;
a gate structure formed on the nanostructures;
an S/D structure formed adjacent to the gate structure; and
an inner spacer layer between the gate structure and the S/D structure.

4. The package structure as claimed in claim 2, further comprising:
a second package layer formed on the first package layer, wherein a top surface of the second package layer is higher than the top surface of the first TIM.

5. The package structure as claimed in claim 1, wherein the lid structure comprises an extending portion which is in direct contact with the first TIM.

6. The package structure as claimed in claim 1, wherein a thermal conductivity of the first TIM is greater than a thermal conductivity of the second TIM.

7. The package structure as claimed in claim 1, wherein a sidewall surface of the first die is aligned with a sidewall surface of the first TIM.

8. The package structure as claimed in claim 1, wherein a sidewall surface of the first TIM is aligned with a sidewall surface of the second TIM.

9. The package structure as claimed in claim 1, wherein a fluidity of the first TIM is greater than the fluidity of the second TIM.

10. A package structure, comprising:
a first die formed over a substrate;
a first package layer surrounding the first die;
a first thermal interface material (TIM) formed on the first die, wherein the first TIM comprises liquid metal; and
a lid structure formed on the first TIM, wherein the lid structure comprises an extending portion which is in direct contact with the first TIM.

11. The package structure as claimed in claim 10, further comprising:
a second die formed adjacent to the first die, wherein the second die is in direct contact with the first TIM.

12. The package structure as claimed in claim 10, further comprising:
a second TIM formed on the first package layer, wherein a top surface of the second TIM is higher than the top surface of the first TIM.

13. The package structure as claimed in claim 12, wherein a thermal conductivity of the first TIM is greater than a thermal conductivity of the second TIM.

14. The package structure as claimed in claim 12, wherein a fluidity of the first TIM is greater than a fluidity of the second TIM.

15. The package structure as claimed in claim 10, further comprising:
a second package layer formed on the first package layer, wherein a top surface of the second package layer is higher than a top surface of the first TIM.

16. The package structure as claimed in claim 10, wherein a sidewall surface of the first die is aligned with a sidewall surface of the first TIM.

17. A method for forming a package structure, comprising:
forming a first die on a substrate;
forming a first package layer surrounding the first die;
forming a second package layer on the first package layer to expose the first die;
forming a first thermal interface material (TIM) on the first die, wherein the first TIM comprises liquid metal; and
forming a second TIM on the second package layer, wherein a top surface of the second TIM is higher than a top surface of the first TIM.

18. The method for forming the package structure as claimed in claim 17, further comprising:
forming a lid structure on the first TIM and the second TIM, wherein the lid structure comprises an extending portion which is in direct contact with the first TIM.

19. The method for forming the package structure as claimed in claim 18, wherein the extending portion of the lid structure is in direct contact with an interface between the second package layer and the second TIM.

20. The method for forming the package structure as claimed in claim 17, further comprising:
forming a second die adjacent to the first die, wherein the second package layer is directly formed on the second die.
